(19) United States
(12) Patent Application Publication
(10) Pub. No.: US 2023/0352608 A1
(43) Pub. Date: Nov. 2, 2023

(54) Geomagnetic and Atmospheric Electric Power Systems

(71) Applicant: Encarnacion Gonzalez, Alice, TX (US)

(72) Inventor: Encarnacion Gonzalez, Alice, TX (US)

(21) Appl. No.: 18/140,747

(22) Filed: Apr. 28, 2023

Related U.S. Application Data
(60) Provisional application No. 63/336,923, filed on Apr. 29, 2022.

(51) Int. Cl. H01L 31/05; B64G 1/44; B64D 41/00; B60L 8/00; H02S 30/10

(52) U.S. Cl. CPC H01L 31/05; B64G 1/443; B64D 41/00; B60L 8/003; H02S 30/10; B64D 2211/00

(57) ABSTRACT

As it is scientifically known all or nearly all celestial bodies have magnetic fields to varying degrees including Earth. Many celestial bodies also have a gaseous atmosphere. The present invention utilizes said magnetic fields and or gaseous atmospheres in conjunction with a plurality of electric grids, coils, or super conducting slats to which varying levels of positive voltage are applied to produce electric power. A plurality of electric grids, coils, or super conducting slats may be installed on automobiles, aircraft, spacecraft, and onto the blades of a wind powered electrical generating system to produce electric power when the blades are in motion.

### CROSS-REFERENCE TO RELATED APPLICATIONS

This application makes reference to U.S. Prov. App. No. 63/336,923 filed Apr. 29, 2022 and incorporates that application, in its entirety, by reference.

### FIELD OF THE INVENTION

This invention relates to renewable and or green power electric systems. Said system may utilize existing geomagnetic fields of celestial bodies in conjunction with moving and or accelerating electrically conductive and or super-conductive materials through said magnetic fields to produce electric power.

### BACKGROUND OF THE INVENTION

Since the Industrial Revolution public outcry regarding pollution and environmental disruption has increased leading to stricter environmental regulations on industries across the board. The generation of power, including petroleum drilling and production and electrical production have been affected. Accordingly renewable and/or green electric power systems are desirable, particularly, those that interact with the environment as it exists to generate electrical power.

### SUMMARY OF THE INVENTION

The present invention relates to renewable and or Green electric power systems. By utilizing existing the geomagnetic fields of celestial bodies including Earth's magnetic field in conjunction with moving and or accelerating electrically conductive and/or super conductive materials through said magnetic fields electric power may be produced. Also, by moving electrically conductive and/or super conductive materials through a gaseous atmosphere the collision of gaseous molecules with the electrically conductive and/or super conductive materials and supporting framework creates electrons which may be collected by electrically conductive and/or super conductive materials with a slight positive charge applied to them. This invention represents a dual mode system that collects electrons, and thus produces electrical current, using both means.

### BRIEF DESCRIPTION OF THE DRAWINGS

FIG. 1 shows a front view of a grid designed to collect and or capture electrons from magnetic fields or the decomposition of gaseous atmospheres from impact with the grid. Said grid may be constructed of individual horizontal or vertical wedge slats constructed of electrically conductive and/or super conductive material. Both ends of each individual slat are embedded into an electrically insulating material. Each individual slat is electrically connected to a system and applied with varying potentials of positive voltage to attract, collect, and/or capture electrons from magnetic fields.

FIG. 2 shows a side view of a portion of FIG. 1 with electrical connections to each slat. The wavy lines shown on FIG. 2 represent Earth's magnetic field. The horizontal lines impacting each wedge slat represent Earth's atmosphere when the slat is in motion. This particular grid embodiment is designed to attract, collect, and/or capture electrons from and create current flow to power electrical systems from an interaction with the Earth's magnetic field and from a physical dissolution of elements in the air on impact with the slat so that freed electrons may be captured and used for power.

FIG. 3a shows a simple illustration of a wind turbine. Strips of electrically conductive material, (not shown) may be installed the full length either within said blades or on the exterior surface of said blades and applied with varying potentials of positive voltage so as to interact with magnetic fields to attract, collect, and or capture electrons from the magnetic fields to cause current flow and or electrical power while blades are in motion.

FIG. 3b shows a more detailed illustration of a single blade of a wind turbine showing the strips of electrically conductive material installed the full length on the exterior surface of said blades and which may be applied with varying potentials of positive voltage so as to interact with a magnetic field to attract, collect, and or capture electrons to cause current flow and or electrical power while the blade is in motion.

FIG. 4 shows a simple illustration showing where strips of electrically conductive material installed on an example portion of an automobile (the grill) or on the exterior surface of said portion of an automobile and which may be applied with varying potentials of positive voltage so as to interact with a magnetic field to attract, collect, and or capture electrons to cause current flow and or electrical power while the automobile is in motion.

FIG. 5a shows a schematic showing how strips of electrically conductive material may be arranged so as to be installed on the exterior surface of a device and after varying potentials of positive voltage are applied, to interact with magnetic fields to attract, collect, and or capture electrons from Earth's magnetic field and or interplanetary magnetic fields to cause current flow and/or electrical power to be generated while the while the device is in motion through a magnetic field.

FIG. 5b shows a schematic diagram showing how strips of electrically conductive material may be installed on the exterior surface of a device and applied with varying potentials of positive voltage so as to interact with magnetic fields to attract, collect, and or capture electrons from the magnetic field to cause current flow and or electrical power while the device is in motion.

### DETAILED DESCRIPTION

As it is scientifically known many celestial bodies have magnetic fields to varying degrees including Earth. These magnetic fields extend far into space. The present invention utilizes said magnetic fields in conjunction with electrically conductive and or super conductive materials applied with varying potentials of positive bias voltage to produce electric power from the aforementioned magnetic fields. Also, by moving and/or accelerating said electrically conductive materials through said magnetic fields electric power may be produced. Electrically conductive materials may have several designs and/or embodiments including, but not limited to, coils, grids, grills, grille bars, strips, V-shaped bars, etc.

Said embodiments may be preferably placed and/or installed onto the exterior surface of vehicles either for highway use or aircraft or spacecraft such as satellites operating within Earth's magnetic field or interplanetary magnetic fields or the magnetic fields present in gaseous atmospheres. Strips and/or coils of electrically conductive material may also be installed onto the blades of wind turbines and may interact with a magnetic field to produce electric power when the blades are in motion. The same type of strips and/or coils may interact with another planet's magnetic field to produce electric power when the blades are in motion.

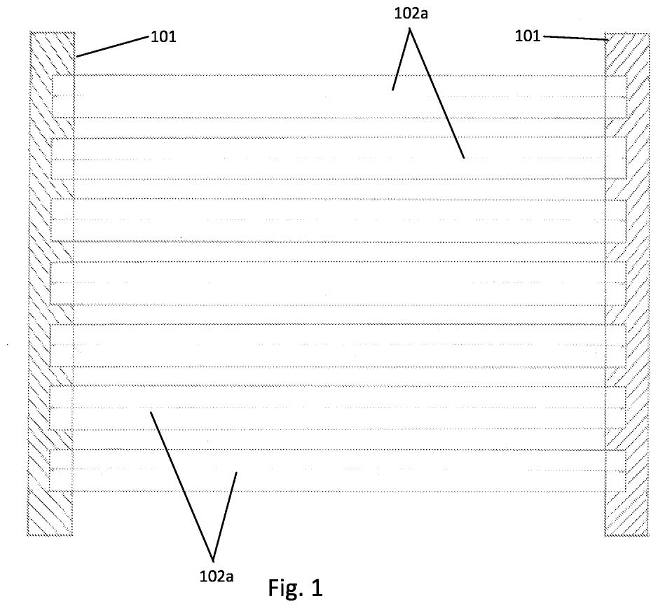

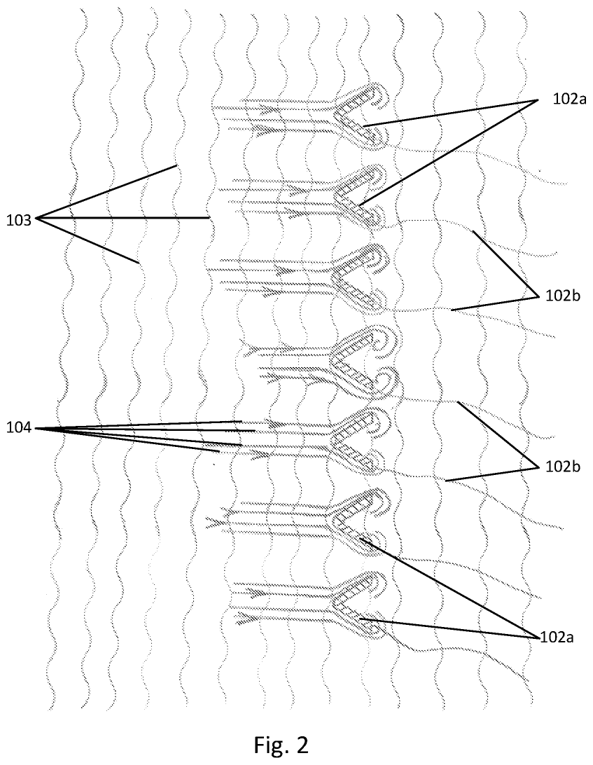

The embodiment described in FIGS. 1 and 2 is but one of several. This particular embodiment is designed to attract, collect, and capture electrons from both Earth's magnetic fields and Earth's atmosphere. FIG. 1 shows the present invention which in this embodiment is comprised of “V”-shaped slats 102a of electrically conductive or super conductive material mounted parallel to one another supported by insulative brackets 101 at each end. Those having skill in the art will recognize that slats 102a may be mounted in numerous other alternative geometries.

FIG. 2 shows wavy lines 103 which represent the Earth's magnetic field along with horizontal lines 104 which represent the Earth's atmosphere impacting said slats 102a when the slats 102a are moving. The slats 102a are supplied with varying potentials of positive voltage to attract, collect, and capture electrons to create current flow to power connected electrical systems. The power generated is conducted to the electrical system by means of wires 102b. Those having skill in the art will recognize that the directional disposition of the magnetic field shown by wavy lines 103 may vary as the direction of the vehicle changes. In such cases the amount of electrical power generated by slats 102a may vary.

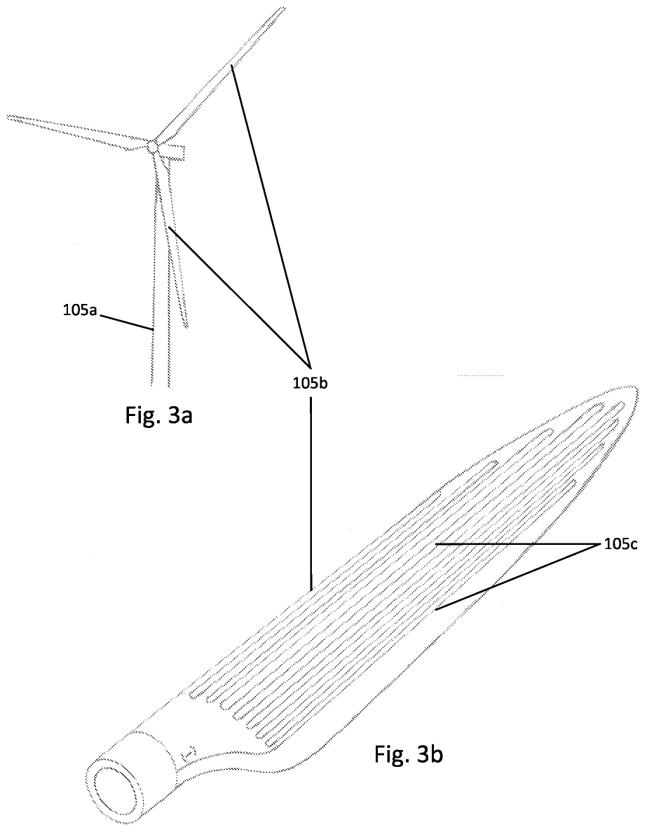

FIGS. 3a and 3b show the blades 105b of wind turbines 105a equipped with arrays of electrically conductive and/or super conductive materials 105c applied along the length of the blades 105b. As the blade 105b rotates through Earth's atmosphere and the Earth's magnetic field electricity may be generated. Said electricity is transferred to an external circuit or battery or other storage device for later use.

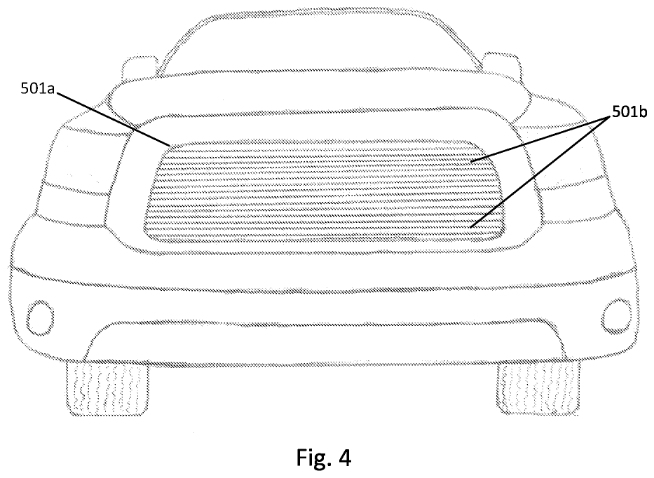

FIG. 4 shows the front of an automobile. In this application, array 501a of electrically conductive and/or super conductive materials are mounted as slats 501b parallel to one another. Those having skill in the art will recognize that slats 501b may be mounted in numerous other alternative geometries. As the slats 501b move through the Earth's atmosphere and the Earth's magnetic field, electricity may be generated. Those having skill in the art will recognize that slats 501b are designed to simultaneously attract, collect, and/or capture electrons and create current to power electrical systems from an interaction with the Earth's magnetic field and from a physical dissolution of elements in the air on impact with slats 501b so that the freed electrons may be captured and used for power.

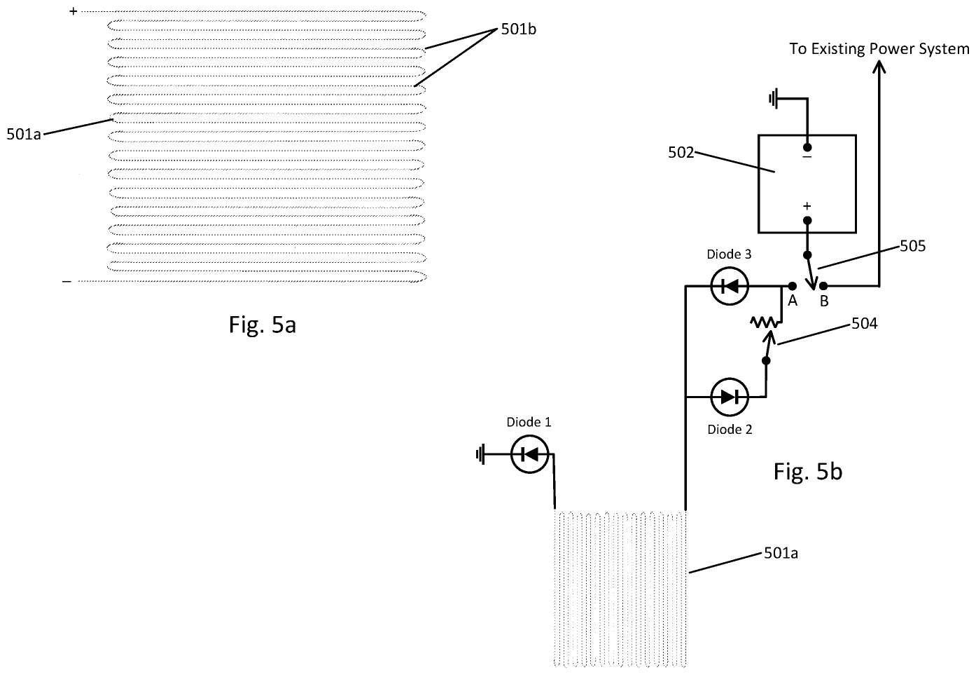

FIG. 5a shows a schematic diagram of an array 501a of electrically conductive and/or super conductive materials mounted as elements of grid (slats) 501b. Such an array 501a of electrically conductive and/or super conductive materials mounted as elements of grid (slats) 501b may be arranged in any geometry. Also, of electrically conductive and/or super conductive materials mounted as elements of grid (slats) 501b may be configured in other configurations including, but not limited to, coils, grids, grills, grille bars, strips, V-shaped bars, etc. Turning now to FIGS. 5a and 5b, a diagram is presented which shows how the invention works. After installing this embodiment of the present invention on highway vehicles, aircraft, spacecraft, or the blades of wind powered generating devices, these objects travel though the Earth's atmosphere and/or the Earth's magnetic field. As the devices travel two reactions may occur.

First, atmospheric gases impacting elements of grid (slats) 501b will be forced to condense and decompose slightly thereby freeing electrons that will be captured by elements of grid (slats) 501b. When switch 505 is in position “A” a variable amount of positive electric biasing current from battery 502 may be applied to the elements of grid (slats) 501b by means of potentiometer 504 and Diode 2. This slight positive charge attracts the freed electrons surrounding elements of grid (slats) 501b.

Second, as the device travels through Earth's magnetic field (or any other magnetic field) an interaction between said magnetic field and the elements of grid (slats) 501b produces electric power. When switch 505 is in position “A” a variable amount of electric biasing current. may be applied to the elements of grid (slats) 501b by means of potentiometer 504 and Diode 2. This slight positive charge induces a current in grid (slats) 501b. The generated current flows back to battery 502 by means of Diode 3.

When electric current consumption is desired, switch 505 is placed at position “B” and electric power flows from battery 502 to the existing power system of the highway vehicle, aircraft, spacecraft, or the wind powered generating device.

Installing said embodiments either as grids and/or as electric coils on spacecraft, the International Space Station (ISS), or other earth orbiting satellites the vacuum environment of space is advantageous. Here, the invention has the potential to attract, collect, and/or capture electrons to create current flow and produce electric power. Also, the invention generates current flow by passing through Earth's magnetic field lines.

It is to be understood that the present invention is not limited to the illustrations and implementations shown. Those skilled in the art will recognize other implementations and uses of the present invention and will recognize that such implementations and uses are implicitly included in the scope of the present invention.

What is claimed:

1. An electric power system that utilizes:
a. high-speed impacts between atmospheric gases and a plurality electric grids, coils, or slats
i. whereupon electrons are freed;
ii. whereupon the freed electrons are captured by the electric grids, coils, or slats when the electric grids, coils, or slats have varying potentials of positive voltage applied to them;
iii. whereupon a current flow to power an electrical system is created;
b. the passage of the plurality of electric grids, coils, or slats to which varying potentials of positive voltage are applied through a geomagnetic field to attract, collect, and/or capture free electrons to create a current flow to power an electrical system is created;
c. wherein at least some of the electric grids, coils, or slats are at least partially constructed of materials chosen from the group consisting of non-super conducting materials and super conducting materials.

2. An electric power system of claim 1 wherein the electrical system supplies energy to an automobile.

3. An electric power system of claim 1 wherein the electrical system supplies energy to an aircraft.

4. An electric power system of claim 1 wherein the electrical system supplies energy to a spacecraft.

5. An electric power system of claim 1 wherein the electrical system supplies energy to a wind powered electrical generating system.

6. An electric power system that utilizes high-speed impacts with atmospheric gases thus freeing electrons to produce electric power by means of a plurality of electric grids, coils, or slats to which varying potentials of positive voltage are applied to attract, collect, and/or capture free electrons to create current flow to power electrical systems wherein at least some of the electric grids, coils, or slats are at least partially constructed of materials chosen from the group consisting of non-super conducting materials and super conducting materials.

7. An electric power system of claim 6 wherein the electrical system supplies energy to an automobile.

8. An electric power system of claim 6 wherein the electrical system supplies energy to an aircraft.

9. An electric power system of claim 6 wherein the electrical system supplies energy to a spacecraft.

10. An electric power system of claim 6 wherein the electrical system supplies energy to a wind powered electrical generating system.

11. An electric power system that utilizes a plurality of electric grids, coils, or slats to which varying potentials of positive voltage are applied and accelerating said electric grids, coils, or slats through a geomagnetic field to create current flow to power electrical systems wherein at least some of the electric grids, coils, or slats are at least partially constructed of materials chosen from the group consisting of non-super conducting materials and super conducting materials.

12. An electric power system of claim 11 wherein the electrical system supplies energy to an automobile.

13. An electric power system of claim 11 wherein the electrical system supplies energy to an aircraft.

14. An electric power system of claim 11 wherein the electrical system supplies energy to a spacecraft.

15. An electric power system of claim 11 wherein the electrical system supplies energy to a wind powered electrical generating system.
